(19) United States
(12) Patent Application Publication
(10) Pub. No.: US 2015/0041206 A1
(43) Pub. Date: Feb. 12, 2015

(54) LAMINATE FOR PRINTED CIRCUIT BOARD, PRINTED CIRCUIT BOARD USING THE SAME, AND METHOD OF MANUFACTURING THE SAME

(71) Applicant: SAMSUNG ELECTRO-MECHANICS CO., LTD., Suwon-si (KR)

(72) Inventors: Joung Gul Ryu, Suwon-si (KR); Keung Jin Sohn, Suwon-si (KR)

(73) Assignee: SAMSUNG ELECTRO-MECHANICS CO., LTD., Suwon-si (KR)

(21) Appl. No.: 14/142,708

(22) Filed: Dec. 27, 2013

(30) Foreign Application Priority Data
Aug. 8, 2013 (KR) 10-2013-0094400

(51) Int. Cl. H05K 1/05; H05K 1/03; H05K 1/11; H05K 3/00

(52) U.S. Cl. CPC H05K 1/056; H05K 3/0064; H05K 1/036; H05K 1/115
USPC 174/266; 156/182; 428/457; 428/416; 428/212; 428/141

(57) ABSTRACT

Disclosed herein is a laminate for a printed circuit board, a printed circuit board using the same, and a method of manufacturing the same. A laminate according to a preferred embodiment includes a primer layer formed on a metal foil and a resin layer formed on the primer layer.

### CROSS REFERENCE TO RELATED APPLICATION

This application claims the benefit of Korean Patent Application No. 10-2013-0094400, filed on Aug. 8, 2013, entitled “Laminate for Printed Circuit Board and Printed Circuit Board Using the Same and Method of Manufacturing for the Same,” which is hereby incorporated by reference in its entirety into this application.

### BACKGROUND OF THE INVENTION

1. Technical Field

The present invention relates to a laminate for a printed circuit board, a printed circuit board using the same, and a method of manufacturing the same.

2. Description of the Related Art

As electronic components become smaller, denser, and thinner, researches to develop a semiconductor package substrate which is thin but highly functional is also being actively conducted. Particularly, in order to implement the multi-chip package (MCP) technology in which multiple semiconductor chips are stacked on one another to be mounted on a single substrate or the package on package (POP) technology in which multiple substrates having chips mounted thereon are stacked on one another, it is necessary to develop a substrate having thermal expansion behavior similar to that of the chip and having an excellent warpage property after the chips are mounted has been required. Further, as recent mobile or multimedia chips have faster speed, highly functional with higher density, overheating at PKG level becomes a serious problem, measures are urgently needed. As such, a recent substrate requires not only one property but requires multi-functionality, and complex properties. Further, in a multimedia POP packages, in addition to thermal issues, low warpage property is required which is caused by thermal expansion of chips and substrate.

Common schemes to meet the requirement include inserting metal having good thermal conductivity such as copper Cu and aluminum Al into a core part of a substrate, or manufacturing a substrate having a metal core made of metal or metal alloy such as Invar with a good radiation property and a thermal expansion property.

Further, as chips are densified, in order to implement micro circuits on printed boards, circuit forming techniques are changing from the existing modified semi-additive process (MSAP) to the semi-additive process (SAP). Accordingly, insulating layers are also changing from the prepreg type to a primer type prepreg or a build-up film type with no glass fabric.

However, in the semi-additive process (SAP), the primer type prepreg has a very thin primer layer in micrometer thick and is vulnerable to the desmear process. Therefore, in order to perform the semi-additive process (SAP), it is necessary to drill via holes in the primer layer with a copper film thereon and to perform a chemical copper process after removing desmear and the copper film. As a result, the process is complicated and costly compared to the process using build-up film. However, it is used in FCCSP because of low thermal expansion due to glass fabric.

In the case of the build-up film, since no additional copper film layer is used, roughness on a resin surface is formed in a separate desmear process after lamination, and circuits are formed using a chemical copper of 1 μm as a seed layer. Therefore, it is more advantageous than existing MSAP in forming micro circuits. However, since it has weaker bonding strength between the resin surface and the chemical copper layer than existing prepreg type since roughness on the resin layer is formed during the desmear process, it causes blisters in later processes or reliability is decreased.

### PRIOR ART DOCUMENT

### Patent Document

(Patent Document 1) Korean Patent Laid-Open Publication No. 2012-0020509

### SUMMARY OF THE INVENTION

The present invention has been made in an effort to provide a printed circuit board in which a build-up film type insulating layer with no glass fabric is used and a primer layer is formed to obtain surface roughness, and a method of manufacturing the same.

According to a first preferred embodiment of the present invention, there is provided a laminate including a primer layer formed on a metal foil and a resin layer formed on the primer layer.

A matt surface of the metal foil may be in contact with the primer layer.

The primer layer may be an epoxy-based resin.

The primer layer may have a thermal expansion coefficient lower than that of the resin layer.

According to a second preferred embodiment of the present invention, there is provided a printed circuit board, including: a plurality of circuit layers formed on a substrate; and an insulating layer interposed between the circuit layers, wherein the insulating layer includes a resin layer and a primer layer formed on the resin layer.

The primer layer may have surface roughness transferred using a matt surface of a metal foil.

The primer layer and the resin layer may form a single layer.

The primer layer may be an epoxy resin.

The primer layer may have a thermal expansion coefficient lower than that of the resin layer.

The printed circuit board may further include a via electrically connecting between the circuit layers.

According to a third preferred embodiment of the present invention, there is provided a method of manufacturing a printed circuit board, including: forming a primer layer on a metal foil; forming a laminate by forming a resin layer on the primer layer; preparing a substrate having circuit layers; and stacking the resin layer of the laminate on the substrate.

The forming of the primer layer may include forming the primer layer on a matt surface of the metal foil.

The primer layer and the resin layer may form a single layer.

The primer layer may be an epoxy resin.

The primer layer may have a thermal expansion coefficient lower than that of the resin layer.

The method may further include, after the stacking of the resin layer, removing the metal foil to transfer surface roughness to the primer layer formed on the matt surface of the metal foil.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view showing a structure of a laminate for a printed circuit board according to a preferred embodiment of the present invention;

FIG. 2 is a cross-sectional view of a printed circuit board according to a preferred embodiment of the present invention; and

FIGS. 3 to 12 are cross-sectional views illustrating a process of a method of manufacturing a printed circuit board according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Laminate for Printed Circuit Board

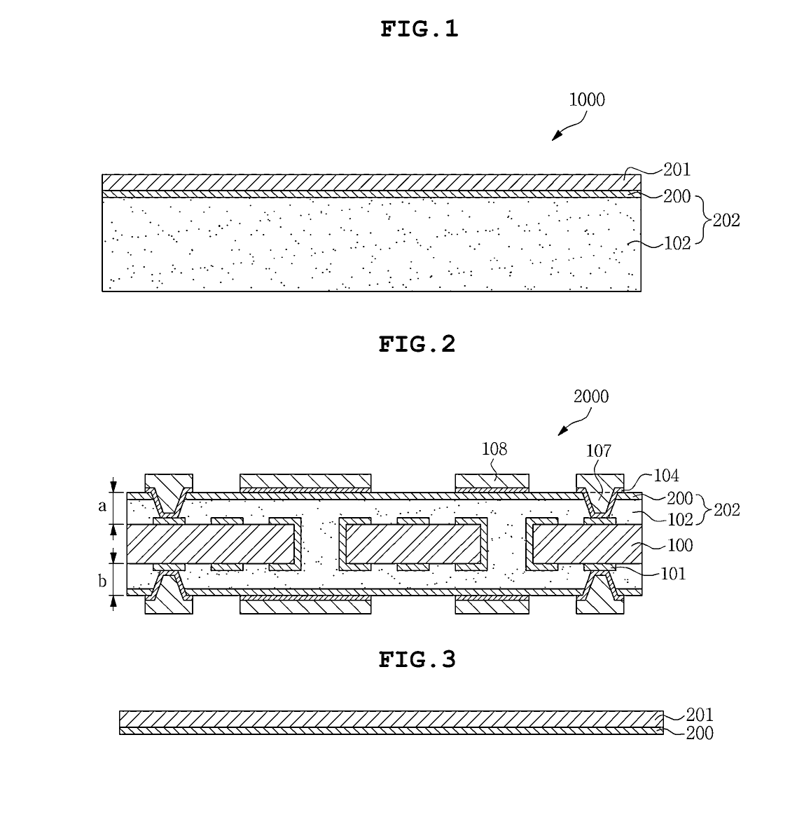

FIG. 1 is a cross-sectional view showing a structure of a laminate for a printed circuit board according to a preferred embodiment of the present invention.

As shown in FIG. 1, the laminate 1000 for a printed circuit board includes a primer layer 200 formed on a metal foil 201, and a resin layer 102 formed on the primer layer 200.

The resin layer 102 may be made of a thermosetting resin such as an epoxy resin or a thermoplastic resin such a polyimide resin.

The metal foil 201 has a matt surface and a shiny surface.

On the matt surface of the metal foil 201, the primer layer 200 may be disposed.

Although the metal foil 201 is made of copper (Cu) in the preferred embodiment, the material of the metal foil 201 is not limited thereto.

In addition, the primer layer 200 may be made of an epoxy-based resin and has a thickness preferably between 1 μm and 5 μm.

Here, the thermal expansion coefficient of the primer layer 200 may be lower than that of the resin layer 102.

Printed Circuit Board

FIG. 2 is a cross-sectional view of a printed circuit board according to a preferred embodiment of the present invention.

As shown in FIG. 2, the printed circuit board 2000 includes a plurality of circuit layers 101 formed on a substrate 100, and insulating layers 202 interposed between the circuit layers 101.

The insulating layers 202 include the resin layer 102 and the primer layer 200 formed on the resin layer 102.

The material of the circuit layers 102 is not specifically limited and any material may be used as long as it is applicable to a conductive metal for a circuit, and is typically copper in the case of a printed circuit board.

In addition, vias 107 may be provided for electrically connecting between the circuit layers 102 and 108.

The primer layer 200 may have surface roughness transferred from the metal foil, which has an Ra value of preferably 250 nm or less.

Although the metal foil 201 is made of copper (Cu) in the preferred embodiment, the material of the metal foil 201 is not limited thereto.

In addition, the primer layer 200 may be made of an epoxy-based resin and may have a thickness between 1 μm and 5 μm. Further, the insulating layer 202 including the primer layer 200 may have the thickness of about 15 μm.

Here, the thermal expansion coefficient of the primer layer 200 may be lower than that of the resin layer 102, so that warpage may be avoided.

The resin layer 102 may be made of a thermosetting resin such as an epoxy resin or a thermoplastic resin such a polyimide resin.

In the printed circuit board 2000, the insulating layer 202 of a build-up film type with no glass fabric is used but the primer layer 200 is formed. As a result, the surface roughness may be transferred simply using the metal foil 201 without performing a desmear process, thereby simplifying the process.

Additionally, the primer layer 200 has a lower thermal expansion coefficient than the resin layer 102, thereby improving warpage issues.

The resin layer 102 and the primer layer 200 formed on the resin layer 102 may be a single-layer.

In addition, as in FIG. 2, the printed circuit board 2000 may have the same values (a) and (b) in thickness in an embodiment, but the present invention is not limited thereto. In the preferred embodiment, values (a) and (b) in thickness are between 15 μm and 20 μm so that it meet the requirements of ultra-thin films.

Although not shown, a printed circuit board having an asymmetric structure in which values (a) and (b) in thickness are different by way of applying an insulating layer to which glass cloth is applied on (a) or (b).

Accordingly, warpage of the printed circuit board 2000 due to thermal deformation may be minimized.

Further, although not shown, the insulating layer 202 may be formed using a coreless substrate such that the insulating layer 202 has one surface of the coreless substrate as the primer layer 200.

The thickness of the insulating layer 202 may be determined as desired, and insulating layers including glass fabric may intersect.

Method of Manufacturing Printed Circuit Board

FIGS. 3 to 12 are views illustrating a process of a method of manufacturing a printed circuit board according to a preferred embodiment of the present invention.

As shown in FIG. 3, the primer layer 202 may be coated or cast on the matt surface of the metal foil 201. Or, a casting process may be performed through a twin slot die. However, the present invention is not limited thereto.

Although the metal foil 201 is made of copper (Cu) in the preferred embodiment, the material of the metal foil 201 is not limited thereto.

In addition, the primer layer 200 may be made of an epoxy-based resin and may have a thickness between 1 μm and 5 μm.

Here, the thermal expansion coefficient of the primer layer 200 may be lower than that of the resin layer 102 to be described below.

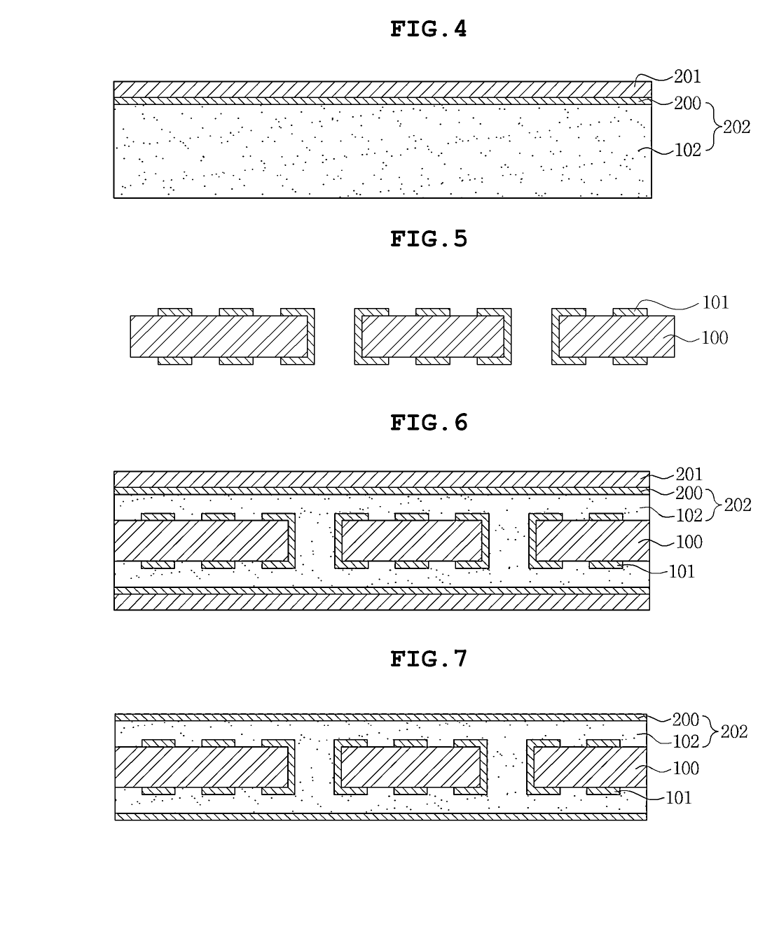

As shown in FIG. 4, the resin layer 102 is formed on the primer layer 200 to prepare a laminate.

The resin layer 102 may be made of a thermosetting resin such as an epoxy resin or a thermoplastic resin such a polyimide resin.

As shown in FIG. 5, substrate 100 having circuit layers 101 are prepared.

The material of the circuit layers 102 is not specifically limited and any material may be used as long as it is applicable to a conductive metal for a circuit, and is typically copper in the case of a printed circuit board.

The substrates may have one or more insulating layers to which typical glass cloth is applied. The substrate may be a coreless substrate.

As shown in FIG. 6, as will be appreciated, the resin layer 102 of the laminate may be stacked either on one surface or both surfaces of the prepared substrates 100.

Further, during the stacking process, the composition materials of the primer layer 200 and the resin layer 102 are identical, so that two layers may be likely to be mixed and not clearly distinguished.

As shown in FIG. 7, after the surface roughness is transferred, etching may be performed to remove the copper foil 201.

The surface roughness of the metal foil 201 may be transferred to the primer layer 200, which has a Ra value of preferably 250 nm or less.

Since the surface roughness may be transferred simply using the metal foil 201 without performing a desmear process, the process may be simplified.

During the precure process, by setting step curing and temperature conditions, a typical filler may be included in the resin layer 102. Since the filler included in the resin layer 102 is less likely to move toward the surface of the resin layer 102, there is less possibility that the filler is exposed even after the etching process to remove the metal foil 201.

During the curing, a covalent bond between the primer layer 200 and the resin layer 102, and a coordinate bond between the primer layer 200 and the metal foil 201 are created to obtain bonding strength, so that the desmear process is not necessary. After etching the metal foil 201, the primer layer 200 and the resin layer 102 may form a single layer.

As shown in FIG. 8, via holes 103 are drilled at positions corresponding to the circuit layers 101 such that they penetrate the insulating layers 202 including the primer layer 200 and the resin layer 102.

The via holes 103 may be formed using a mechanical drill or a laser drill but is not limited thereto. The laser drill may be a CO2 laser drill or a YAG laser drill, but is not limited thereto.

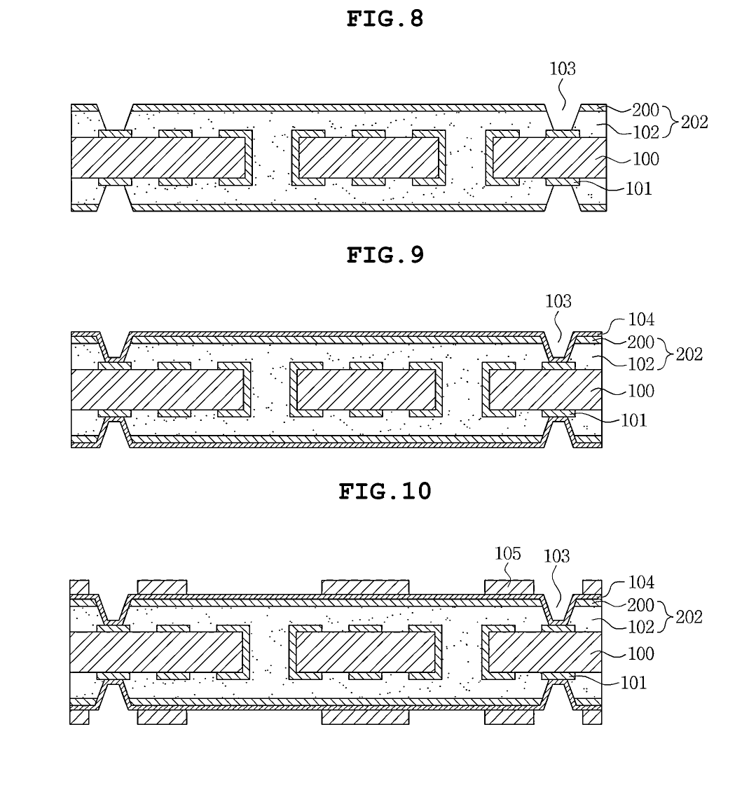

As shown in FIG. 9, a seed layer 104 is formed on the insulating layer 202 and on the inner walls of the via holes 103.

Although the seed layer 104 may be formed using an electroless plating technique or a sputtering technique, the present invention is not limited thereto but may use any technique known in the art.

In this embodiment, the seed layer 202 is formed using an electroless plating technique.

Since the electroless copper plating is plating on insulators, it is considered that no ion reaction having electric charge happens. The electroless copper plating is conducted by precipitation, which is facilitated by a catalyst. In order to precipitate copper from a plating solution, a catalyst should be attached on the surface of a material to be plated. This means that electroless copper plating requires a lot of preprocessing.

In an embodiment, an electroless copper plating process includes a cleanet process, a soft etching process, a pre-catalyst process, a catalyst process, an accelerator process, an electroless copper plating process, and an antioxidant process.

In the cleanet process, oxide or foreign material, especially oil and fat existing on the upper and lower surfaces of a copper film are removed by chemicals containing an acid or alkali surfactant, and the surfactant is completely cleaned. In the soft etching process, fine roughness (e.g., 1 μm to 2 μm) is made on the upper and lower surfaces of the copper film, such that copper particles are evenly attached during the plating process, and contaminants which were not processed during the cleanet process are removed. In the pre-catalyst process, a base substrate 100 is soaked in a catalyst chemical at a low concentration, so as to prevent chemicals used in the catalyst process from being contaminated or the concentration from being changed. Moreover, the base substrate 100 is soaked in a chemical bath of the same component in advance, such that the catalyst process is facilitated. Preferably, this pre-catalyst process is performed using a catalyst chemical diluted to 1% to 3%.

In the catalyst process, catalyst particles are applied onto the copper film of the base substrate 100 and the surface of an insulating resin layer 120 (i.e., side wall of a via hole). Preferably, a Pd—Sn compound is used, and the Pd—Sn compound is coupled with the plated particles, Cu2+ and Pd2+, to facilitate the plating. In the electroless copper plating process, the plating solution is preferably made of CuSO4, HCHO, NaOH and other stabilizer. In order to maintain the plating reaction, a chemical reaction should be balanced, and thus it is important to control composition of the plating solution. In order to keep the composition, supply of insufficient components, mechanical stirring, circulation system of the plating solution should be operated well. A filter to filter residuals from the reaction is required, by which usage time of the plating solution may be extended.

In the antioxidant process, in order to prevent a plating film from being oxidized due to alkali components remaining after the electroless copper plating, an antioxidant film is coated on the entire surface.

However, since the electroless copper plating process generally has a weaker physical property compared to the electro copper plating, it is formed thinner.

As shown in FIG. 10, a plating resist 105 may be selectively formed on the seed layer 104.

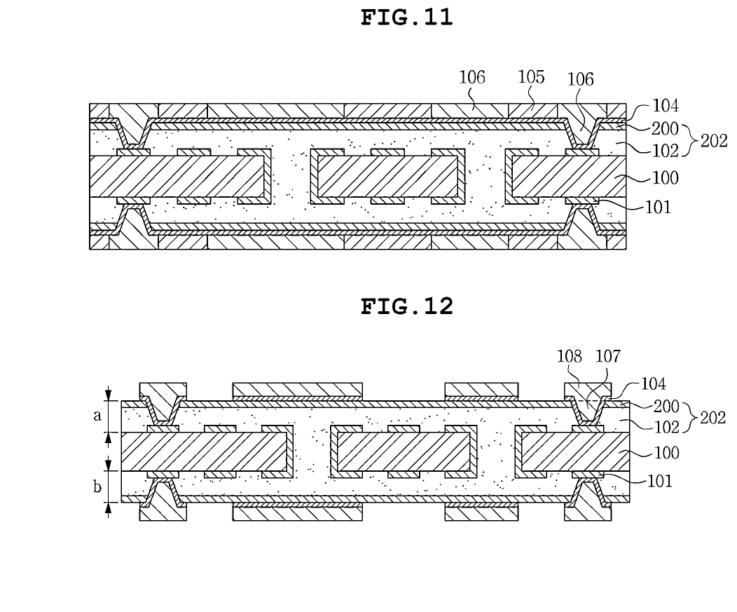

As shown in FIG. 11, plating is performed on a portion other than the portion on which the plating resist 105 is formed.

As shown in FIG. 12, after the plating resist 105 is removed, the seed layer 104 is etched, and the circuit layer 108 and via 107 is formed.

In addition, the printed circuit board 2000 may have the same values (a) and (b) in thickness in an embodiment, but the present invention is not limited thereto. In the preferred embodiment, values (a) and (b) in thickness are between 15 μm and 20 μm so that it may meet the requirements of ultra-thin films.

Although not shown, a printed circuit board may have an asymmetric structure in which values (a) and (b) in thickness are different by way of applying an insulating layer 202 to which glass cloth is applied on (a) or (b).

Accordingly, warpage of the printed circuit board 2000 due to thermal deformation may be minimized.

Further, although not shown, a coreless substrate may be applied such that an insulating layer 202 having the primary layer 200 as one surface of the coreless substrate may be formed.

The thickness of the insulating layer 202 may be determined as desired, and insulating layers including glass fabric may intersect.

In the printed circuit board 2000, the insulating layer of a build-up film type with no glass fabric is used but the primer layer 200 is formed. As a result, the surface roughness may be transferred simply using a metal foil with no need of desmear process, thereby simplifying the process.

Further, since the primer layer has a thermal expansion coefficient lower than that of the build-up film, problem of substrate warpage can be overcome.

As set forth above, according to the printed circuit board according to the embodiments of the present invention, the insulating layer of a build-up film type with no glass fabric is used but the primer layer is formed, and thus the surface roughness may be transferred simply using a metal foil without performing a desmear process, thereby simplifying the process.

Further, since the primer layer has a thermal expansion coefficient lower than that of the build-up film, problem of substrate warpage can be overcome.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A laminate for a printed circuit board, comprising:
a primer layer formed on a metal foil; and
a resin layer formed on the primer layer.

2. The laminate as set forth in claim 1, wherein a matt surface of the metal foil is in contact with the primer layer.

3. The laminate as set forth in claim 1, wherein the primer layer is an epoxy-based resin.

4. The laminate as set forth in claim 1, wherein the primer layer has a thermal expansion coefficient lower than that of the resin layer.

5. A printed circuit board, comprising:
a plurality of circuit layers formed on a substrate; and
an insulating layer interposed between the circuit layers,
wherein the insulating layer includes a resin layer and a primer layer formed on the resin layer.

6. The printed circuit board as set forth in claim 5, wherein the primer layer has surface roughness transferred using a matt surface of a metal foil.

7. The printed circuit board as set forth in claim 5, wherein the primer layer and the resin layer form a single layer.

8. The printed circuit board as set forth in claim 5, wherein the primer layer is an epoxy resin.

9. The printed circuit board as set forth in claim 5, wherein the primer layer has a thermal expansion coefficient lower than that of the resin layer.

10. The printed circuit board as set forth in claim 5, further comprising a via electrically connecting the circuit layers to one another.

11. A method of manufacturing a printed circuit board, comprising:
forming a primer layer on a metal foil;
forming a laminate by forming a resin layer on the primer layer;
preparing a substrate having circuit layers; and
stacking the resin layer of the laminate on the substrate.

12. The method as set forth in claim 11, wherein the forming of the primer layer includes forming the primer layer on a matt surface of the metal foil.

13. The method as set forth in claim 11, wherein the primer layer and the resin layer form a single layer.

14. The method as set forth in claim 11, wherein the primer layer is made of an epoxy resin.

15. The method as set forth in claim 11, wherein the primer layer has a thermal expansion coefficient lower than that of the resin layer.

16. The method as set forth in claim 11, further comprising, after the stacking of the resin layer, removing the metal foil to transfer surface roughness to the primer layer formed on the matt surface of the metal foil.
